(19) United States
(12) Patent Application Publication
(10) Pub. No.: US 2008/0122081 A1
(43) Pub. Date: May 29, 2008

(54) Method of fabricating electronic device having sacrificial anode, and electronic device fabricated by the same

(75) Inventors: Young-Lyong Kim, Seongnam-si (KR); Young-Shin Choi, Cheonan-si (KR); Jong-Gi Lee, Yongin-si (KR); Kun-Dae Yeom, Cheonan-si (KR); Eun-Chul Ahn, Yongin-si (KR)

Correspondence Address: HARNESS, DICKEY & PIERCE, P.L.C., P.O. BOX 8910, RESTON, VA, 20195, US

(73) Assignee: Samsung Electronics Co., Ltd.

(21) Appl. No.: 11/902,260

(22) Filed: Sep. 20, 2007

(30) Foreign Application Priority Data
Nov. 23, 2006 (KR) 10-2006-0116328

(51) Int. Cl. H01L 23/488; H01L 21/44

(52) U.S. Cl. 257/737; 438/613; 257/E23.023; 257/E21.476

(57) ABSTRACT

According to an example embodiment, a method of fabricating an electronic device may include preparing a substrate with a first area and a second area. A metal interconnection may be formed on the substrate extending from the first area to the second area. An insulating layer may be formed on the substrate. A sacrificial pattern electrically connected to the metal interconnection and serving as a sacrificial anode for cathodic protection against corrosion of the metal interconnection may be formed on the second area. An opening to expose the metal interconnection on the first area may be formed by patterning the insulating layer. An electronic device fabricated by a method according to an example embodiment may include a substrate, a metal interconnection, an insulating layer, and/or a sacrificial pattern.

### PRIORITY STATEMENT

This application claims priority under 35 U.S.C. §119 Korean Patent Application No. 10-2006-0116328, filed on Nov. 23, 2006, in the Korean Patent Office, the entire contents of which are incorporated herein by reference.

### BACKGROUND

Electronic devices may be increasingly developed for smaller size and higher performance applications. Technology for enhancing integration densities in such applications may include reduction of the components in electronic devices and increasing the layout efficiency of those components. For example, fabricating a semiconductor device may include forming individual transistors on a semiconductor substrate constituting an integrated circuit, forming a metal interconnection to input/output electrical signals to/from the integrated circuit, and packaging the semiconductor substrate including the metal interconnection.

Forming an electronic product may include forming a printed circuit board card by connecting a semiconductor package of a single chip module to a printed circuit board (PCB) using surface mount technology (SMT) or pin through hole (PTH) mount technology. The PCB may include a plurality of chip regions onto which the semiconductor package of the single chip module may be mounted, and may further include a sawing lane between the chip regions. For example, a plurality of single chip modules may be mounted onto a single PCB, and the PCB may be cut along the sawing lane, thereby providing an electronic device in which one single chip module is mounted onto one chip region.

Since the PCB may be only a partially completed product, it may be finished when a passive device and an active device are mounted in separate industries, for example, package industries and/or assembly industries. In the package industries and assembly industries, a semiconductor package may be mounted onto the PCB. To drive the semiconductor package mounted onto the PCB, a metal interconnection may be used to input/output electrical signals to/from the semiconductor package. The metal interconnection may be formed on the PCB using a copper layer, for example. The copper layer may be oxidized when exposed to air, thereby forming an oxide layer. To prevent oxidization of the copper layer, PCB manufacturers may apply surface treatment to the PCB being finished to improve mounting of the passive and active devices. For example, a nickel layer and a gold layer may be formed sequentially on the copper layer of the PCB. However, the technique used conventionally to prevent oxidization of the copper layer on the PCB using gold may increase the cost of production. Moreover, the technique used conventionally to prevent oxidization of the copper layer using gold may cause a problem in drop reliability of electronic products, for example, the reliability of mobile phones after they are dropped. This may be because a contact problem has occurred in the interfaces of a multilayer structure including the copper layer/nickel layer/gold layer from an impact upon the test of the drop reliability of an electronic product.

Another technique to reduce or prevent oxidization of the copper layer on the PCB may use an organic chemical compound in the form of alkyl imidazole, to be formed on the copper layer to the thickness of 0.2 to 0.4 μm selectively. For example, a method of reducing or preventing oxidization of a copper layer may include forming a copper interconnection on the PCB, forming an insulating layer with an opening to expose the copper interconnection on a ball or pad region, and filling the opening with an organic solderability preservative (OSP) layer. The OSP layer used in this method may be suitable for a relatively small circuit and may be an environment-friendly substance. However, since the OSP layer may be composed of an organic substance, if the product is handled without the necessary care, the mounting pad may be scratched and the OSP layer may be broken. This may expose the copper oxidize it. Moreover, when the PCB is kept for a long time before mounting a semiconductor package, a problem in a mounting reliability of the PCB may occur.

### SUMMARY

According to an example embodiment, a method of fabricating an electronic device may include preparing a substrate with a first area and a second area. A metal interconnection may be formed on the substrate extending from the first area to the second area. An insulating layer may be formed on the substrate. A sacrificial pattern electrically connected to the metal interconnection and serving as a sacrificial anode for cathodic protection against corrosion of the metal interconnection may be formed on the second area. An opening to expose the metal interconnection on the first area may be formed by patterning the insulating layer.

The substrate may be a semiconductor substrate, a rigid printed circuit board substrate, or a flexible printed circuit board substrate, for example. The metal interconnection may be formed of a copper layer. The sacrificial pattern may be composed of iron (Fe), zinc (Zn), aluminum (Al), nickel (Ni), tin (Sn), or lead (Pb). The sacrificial pattern may penetrate the insulating layer on the second area to contact the metal interconnection.

The method may also include forming a conductive pattern on the metal interconnection exposed by the opening, the conductive pattern being a gold bump, a tin bump, or a solder bump. The first area may be a circuit area, and the second area may be a dummy area or a cut area. The method may also include cutting the substrate at the second area to remove the sacrificial pattern.

According to another example embodiment, a method of fabricating a semiconductor package may include preparing a semiconductor substrate with a first area and a second area. A lower metal pattern may be formed on the first area of the semiconductor substrate. A lower insulating layer with a via hole may be formed on the semiconductor substrate to expose the lower metal pattern. A metal interconnection electrically connected to the lower metal pattern by the via hole and extending from the first area to the second area may formed on the lower insulating layer. An upper insulating layer including a first opening exposing the metal interconnection on the second area may be formed on the semiconductor substrate. A sacrificial pattern electrically connected to the metal interconnection exposed by the first opening may be formed to serve as a sacrificial anode for cathodic protection. A second opening may be formed to expose the metal interconnection on the first area by patterning the upper insulating layer.

The metal interconnection may be formed of a copper layer. The sacrificial pattern may be composed of iron (Fe), zinc (Zn), aluminum (Al), nickel (Ni), tin (Sn), or lead (Pb). A conductive pattern may be formed on the metal interconnection exposed by the second opening, the conductive pattern being a gold bump, a tin bump, or a solder bump. The first area may be a circuit area, and the second area may be a dummy area or a cut area.

An electronic device fabricated by a method according to an example embodiment may include a substrate, a metal interconnection, an insulating layer, and/or a sacrificial pattern. The substrate may include a first area and a second area. The metal interconnection may be formed on the substrate and extend from the first area to the second area. The insulating layer may be formed on the substrate and include an opening exposing the metal interconnection on the first area. The sacrificial pattern may penetrate the insulating layer on the second area and be electrically connected to the metal interconnection. The sacrificial pattern may be configured to serve as a sacrificial anode for cathodic protection against corrosion of the metal interconnection.

The substrate may be a semiconductor substrate, a rigid printed circuit board substrate, or a flexible printed circuit board substrate. The metal interconnection may include a copper layer. The sacrificial pattern may be composed of iron (Fe), zinc (Zn), aluminum (Al), nickel (Ni), tin (Sn), or lead (Pb). The sacrificial pattern may be a plated metal layer.

The device may also include a conductive pattern formed on the metal interconnection exposed by the opening. The conductive pattern may be a gold bump, a tin bump, or a solder bump.

The device may also include a lower insulating layer and/or a metal pad. The lower insulating layer may be formed between the substrate and the metal interconnection. The metal pad may be electrically connected to the metal interconnection and formed between the lower insulating layer and the substrate.

The first area may be a circuit area, and the second area may be a dummy area or a cut area.

### BRIEF DESCRIPTION OF THE DRAWINGS

The above and other features and advantages of example embodiments will become more apparent by describing in detail example embodiments with reference to the attached drawings. The accompanying drawings are intended to depict example embodiments and should not be interpreted to limit the intended scope of the claims. The accompanying drawings are not to be considered as drawn to scale unless explicitly noted.

FIGS. 1A through 1E are sectional views illustrating a method of fabricating an electronic device according to an example embodiment.

FIG. 2 is a sectional view illustrating an electronic device processed according to an example embodiment.

FIGS. 3A through 3D are sectional views illustrating a method of fabricating an electronic device according to another example embodiment.

### DESCRIPTION OF EXAMPLE EMBODIMENTS

Detailed example embodiments are disclosed herein. However, specific structural and functional details disclosed herein are merely representative for purposes of describing example embodiments. Example embodiments may, however, be embodied in many alternate forms and should not be construed as limited to only the embodiments set forth herein.

Accordingly, while example embodiments are capable of various modifications and alternative forms, embodiments thereof are shown by way of example in the drawings and will herein be described in detail. It should be understood, however, that there is no intent to limit example embodiments to the particular forms disclosed, but to the contrary, example embodiments are to cover all modifications, equivalents, and alternatives falling within the scope of example embodiments. Like numbers refer to like elements throughout the description of the figures.

It will be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of example embodiments. As used herein, the term “and/or” includes any and all combinations of one or more of the associated listed items.

It will be understood that when an element is referred to as being “connected” or “coupled” to another element, it may be directly connected or coupled to the other element or intervening elements may be present. In contrast, when an element is referred to as being “directly connected” or “directly coupled” to another element, there are no intervening elements present. Other words used to describe the relationship between elements should be interpreted in a like fashion (e.g., “between” versus “directly between”, “adjacent” versus “directly adjacent”, etc.).

The terminology used herein is for the purpose of describing particular embodiments only and is not intended to be limiting of example embodiments. As used herein, the singular forms “a”, “an” and “the” are intended to include the plural forms as well, unless the context clearly indicates otherwise. It will be further understood that the terms “comprises”, “comprising,”, “includes” and/or “including”, when used herein, specify the presence of stated features, integers, steps, operations, elements, and/or components, but do not preclude the presence or addition of one or more other features, integers, steps, operations, elements, components, and/or groups thereof.

It should also be noted that in some alternative implementations, the functions/acts noted may occur out of the order noted in the figures. For example, two figures shown in succession may in fact be executed substantially concurrently or may sometimes be executed in the reverse order, depending upon the functionality/acts involved.

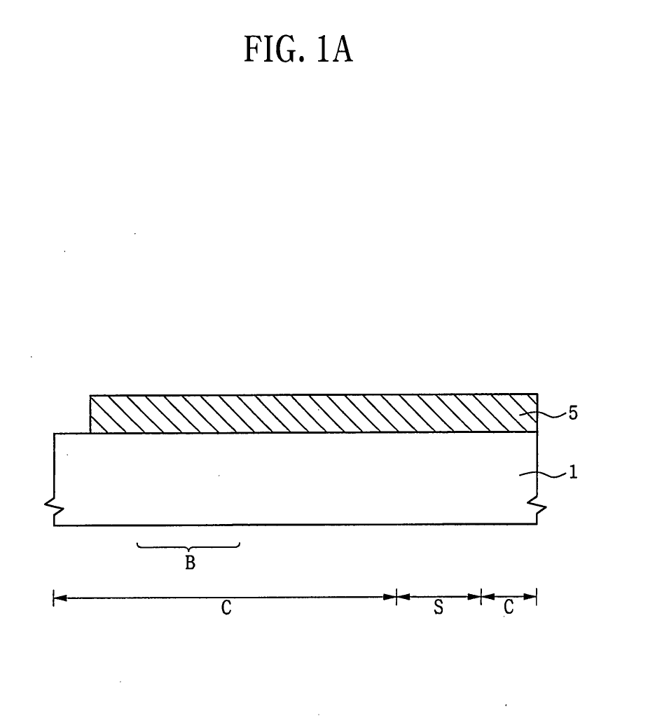

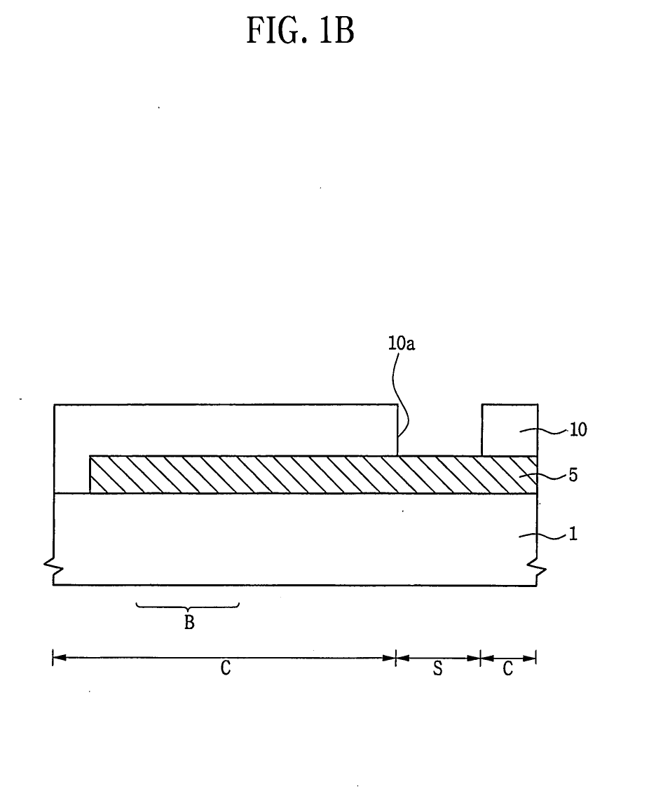

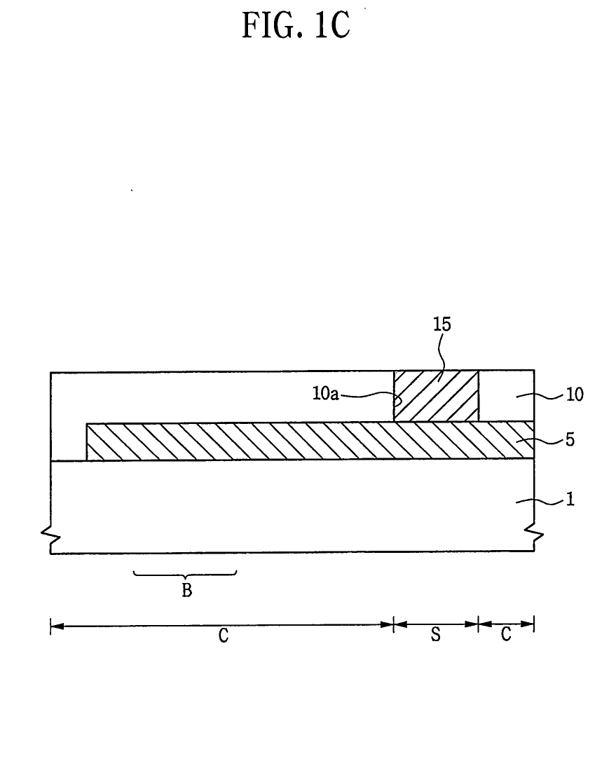

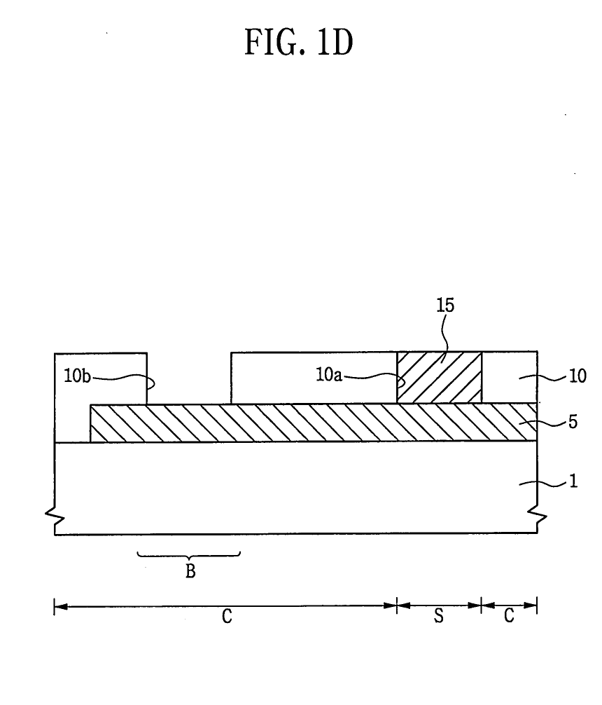

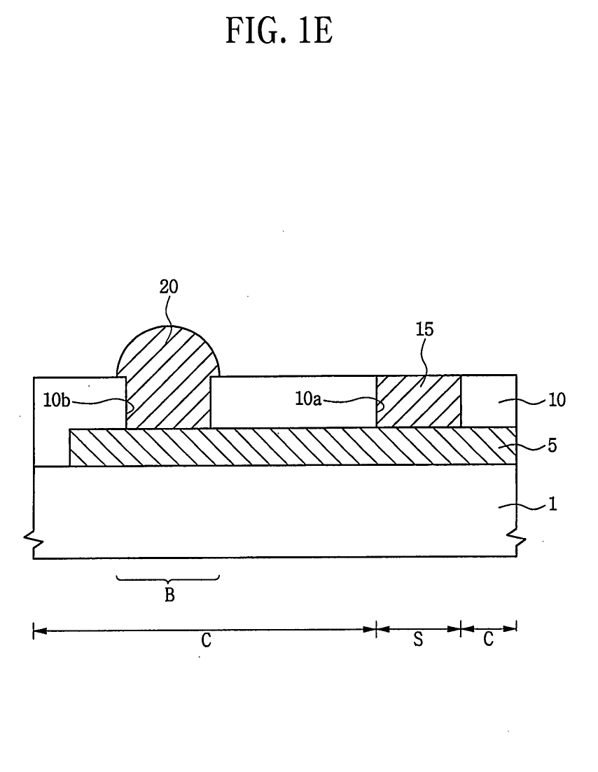

FIGS. 1A through 1E are sectional views illustrating a method of fabricating an electronic device according to an example embodiment.

As illustrated in FIG. 1A, a substrate 1, including a first area C and a second area S, may be prepared. The substrate 1 may be a printed circuit board (PCB), a semiconductor substrate, etc. The PCB may be a rigid substrate or a flexible substrate, for example.

The first area C may be a circuit area, and the second area S may be a dummy area. For example, the second area S may be used as a cut area. The first area C may include a ball landing portion B.

A metal interconnection 5 extending from the first area C to the second area S may be formed on the substrate 1. The metal interconnection 5 may be formed of a copper layer, an aluminum layer, or the like.

As illustrated in FIG. 1B, an insulating layer 10 may be formed on the substrate having the metal interconnection 5. The insulating layer 10 may be a silicon oxide layer, a silicon nitride layer, a polyimide layer or a solder resist layer, for example. A first opening 10a may be formed on the second area S by patterning the insulating layer 10. A given region of the metal interconnection 5 may be exposed by the first opening 10a.

As illustrated in FIG. 1C, a sacrificial pattern 15 may be formed on the metal interconnection 5 exposed by the first opening 10a. The sacrificial pattern 15 may serve as a sacrificial anode used in cathodic protection to reduce or prevent corrosion of the metal interconnection 5. The sacrificial pattern 15 may be formed including an iron (Fe) element, a zinc (Zn) element, an aluminum (Al) element, a nickel (Ni) element, a tin (Sn) element, and/or a lead (Pb) element. The sacrificial pattern 15 may be formed of a metal layer using a plating or similar method. For example, the sacrificial pattern 15 may be formed of a Zn layer by an electrolytic plating method.

As illustrated in FIG. 1D, a second opening 10b may be formed by patterning the insulating layer 10. The second opening 10b may expose the metal interconnection 5 positioned on the first area C. The second opening 10b may be formed on the ball landing portion B. Although the metal interconnection 5 may be exposed by the second opening 10b, the metal interconnection 5 may be impeded or prevented from corroding because the sacrificial pattern 15 in contact with the metal interconnection 5 may act as a sacrificial anode in a cathodic protection scheme. For example, the sacrificial pattern 15 may itself corrode instead of the metal interconnection 5.

Accordingly, even if the second opening 10b remains open for a significant amount of time, the metal interconnection 5 exposed by the second opening 10b may not corrode. For example, if the substrate 1 is a PCB, the PCB may be maintained in a partially completed state for an extended period of time without corrosion of the metal interconnection 5. Therefore, the use of a conventional organic solderability preservative (OSP) layer to prevent oxidation of a metal surface may be reduced or omitted.

As illustrated in FIG. 1E, a conductive pattern 20 may be formed on the metal interconnection 5 exposed by the second opening 10b. The conductive pattern 20 may be formed of a metal bump, for example, a gold bump, a tin bump or a solder bump, or the like.

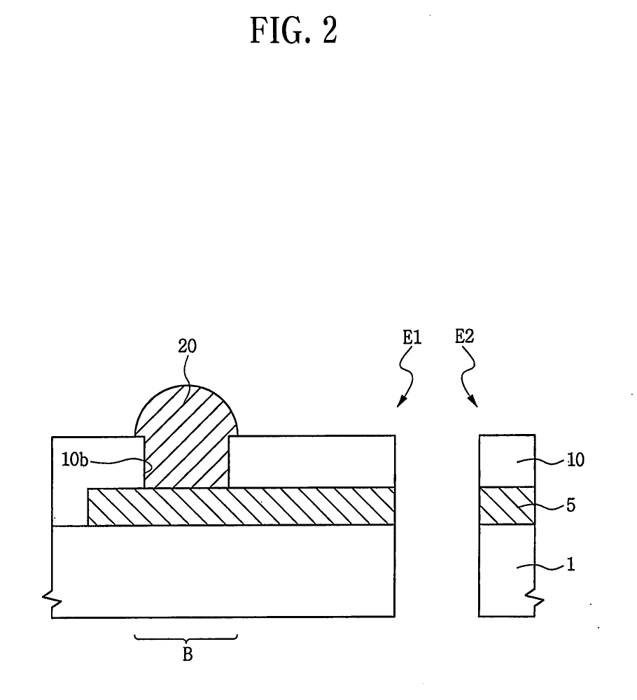

When the second area S is a cut area, the first area C may be separated by cutting the second area S as illustrated in FIG. 2. Thus, a plurality of electronic devices E1 and E2 may be formed.

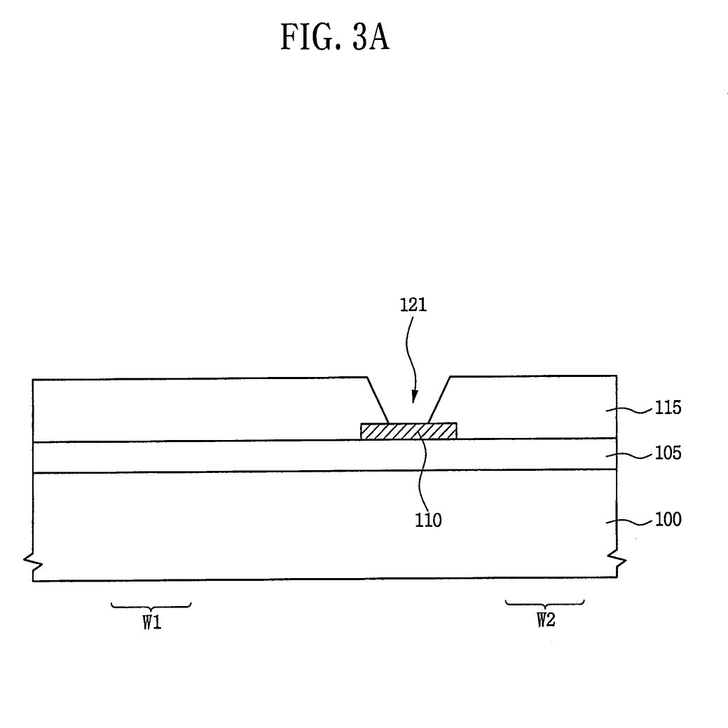

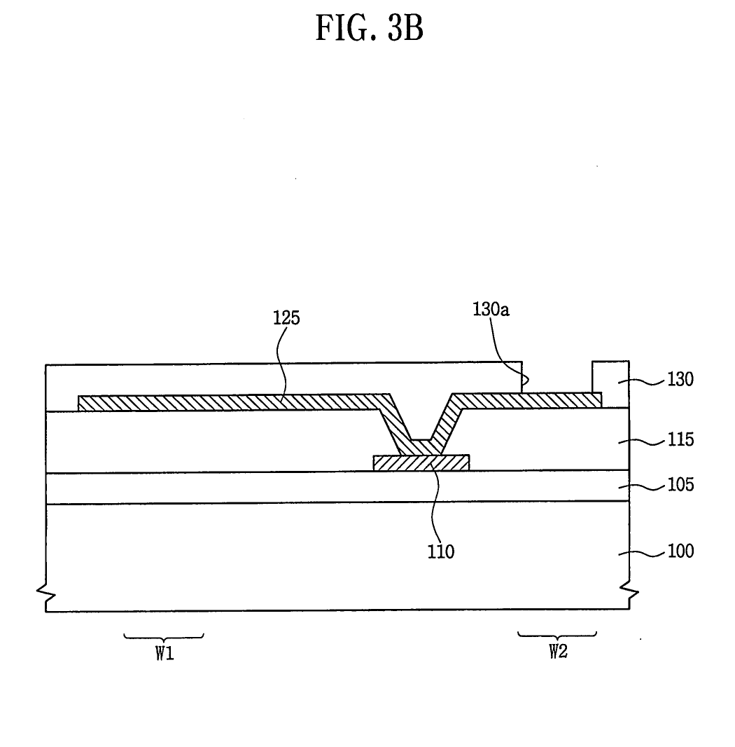

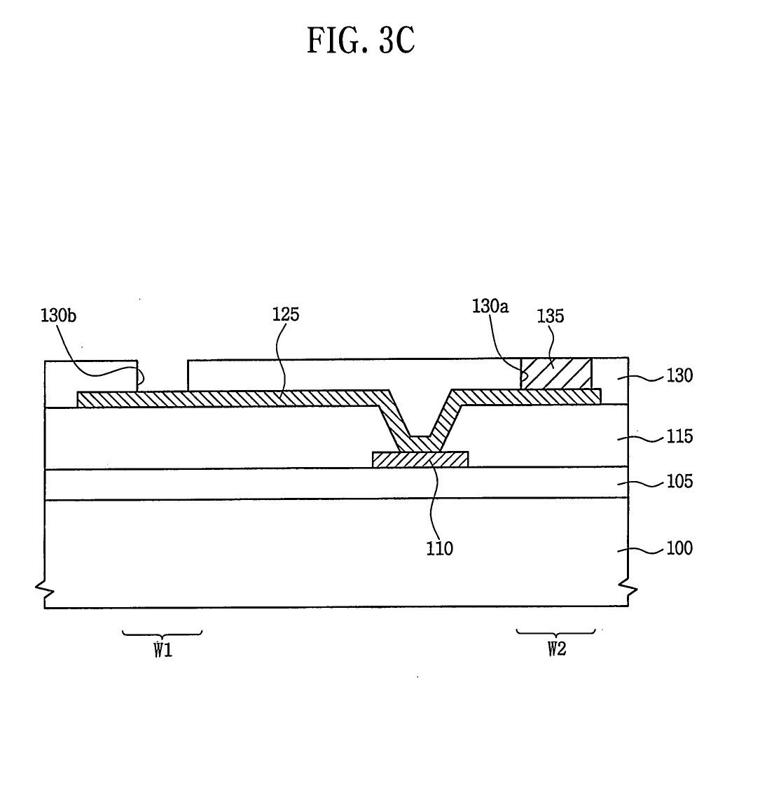

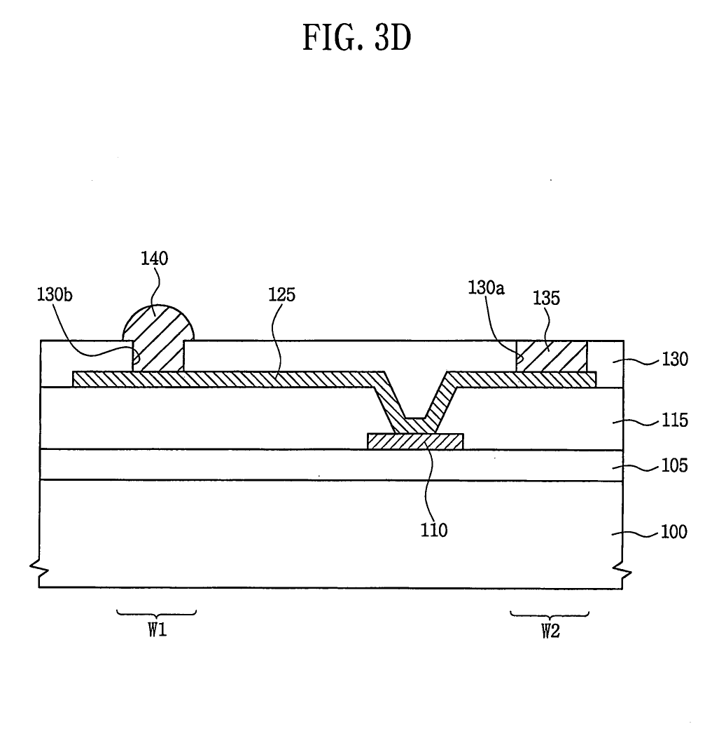

FIGS. 3A through 3D are sectional views illustrating a method of fabricating an electronic device according to another example embodiment.

As illustrated in FIG. 3A, a semiconductor substrate 100, including a first area W1 and a second area W2, may be prepared. For example, the semiconductor substrate 100 may be a semiconductor wafer with an integrated circuit, the first area W1 may be a ball landing portion, and/or the second area W2 may be a dummy area or a cut area, or the like. An interlayer insulating layer 105 may be formed on the semiconductor substrate 100. The interlayer insulating layer 105 may be formed of a silicon oxide layer or the like. A lower metal pattern 110 may be formed on the interlayer insulating layer 105. The lower metal pattern 110 may be formed of a metal layer, and may be electrically connected to the integrated circuit. For example, the lower metal pattern 110 may be a ground pad, a power pad or a signal pad, or the like.

A lower insulating layer 115 may be formed on the substrate having the lower metal pattern 110 thereon. A via hole 121 exposing the lower metal pattern 110 may be formed by patterning the lower insulating layer 115.

As illustrated in FIG. 3B, a metal interconnection 125 may be formed on the lower insulating layer 115 on the substrate. The metal interconnection 125 may be electrically connected to the lower metal pattern 110 by the via hole 121. The metal interconnection 125 may be formed of a copper layer, an aluminum layer, or the like.

An upper insulating layer 130 may be formed on the metal interconnection 125 on the substrate. A first opening 130a exposing the metal interconnection 125 and positioned on the second area W2 may be formed by patterning the upper insulating layer 130.

As illustrated in FIG. 3C, a sacrificial pattern 135 may be formed on the metal interconnection 125 exposed by the first opening 130a. A second opening 130b exposing the metal interconnection 125 and positioned on the first area W1 may be formed by patterning the upper insulating layer 130. The sacrificial pattern 135 may serve as a sacrificial anode used in cathodic protection.

As illustrated in FIG. 3D, a conductive pattern 140 may be formed on the metal interconnection 125 exposed by the second opening 130b. The conductive pattern 140 may be formed of a metal bump, for example a gold bump, a tin bump or a solder bump, or the like.

When the second area W2 is a cut area, a process of cutting the second area W2 may be performed. Thus, a plurality of single chip modules may be formed, which may be packaged at the wafer level.

Referring to FIG. 1E, an electronic device fabricated according to an example embodiment will be described below.

As illustrated in FIG. 1E, a metal interconnection 5 may be formed on a substrate 1 of a first area C and a second area S. The substrate 1 may be a printed circuit board (PCB), a semiconductor substrate, etc. The PCB may be used as a rigid substrate or a flexible substrate.

The first area C may be a circuit area, and may include a ball landing portion B. The second area S may be a dummy area, or a cut area, for example. If the second area S is used as a cut area, the substrate 1 may be a PCB, a semiconductor wafer, or the like.

The metal interconnection 5 extending from the first area C to the second area S may be formed on the substrate 1. The metal interconnection 5 may include a copper layer, an aluminum layer, etc.

An insulating layer 10 may be formed on the substrate having the metal interconnection 5. The insulating layer 10 may include a first opening 10a exposing the metal interconnection 5 positioned on the second area S, and a second opening 10b exposing the metal interconnection 5 positioned on the ball landing portion B. The insulating layer 10 may be formed of a silicon oxide layer, a silicon nitride layer, a polyimide layer, or a solder resist layer, or the like.

A sacrificial pattern 15 may be electrically connected to the metal interconnection 5 through the first opening 10a of the insulating layer 10. For example, the metal interconnection 5 and the sacrificial pattern 15 may directly contact each other through the first opening 10a of the insulating layer 10. The sacrificial pattern 15 may include a Fe element, a Zn element, an Al element, a Ni element, a Sn element, or a Pb element, or the like. The sacrificial pattern 15 may be formed, for example, by a plated metal layer.

The sacrificial pattern 15 may serve as a sacrificial anode used in cathodic protection. For example, the sacrificial pattern 15 may be a sacrificial anode and the metal interconnection 5 a protected cathode. Accordingly, the sacrificial pattern 15 may itself corrode instead of the metal interconnection 5 during a process that may expose the metal interconnection 5 by the second opening 10b. Thus, since corrosion of the metal interconnection 5 may be impeded or prevented during fabrication of an electronic device, including possible extended storage of a partially completed product, deterioration of electrical characteristics in the completed electronic device may be reduced or prevented.

A conductive pattern 20 may be formed on the metal interconnection 5 exposed by the second opening 10b. The conductive pattern 20 may be a metal bump, for example, a gold bump, a tin bump, or a solder bump, or the like.

Referring to FIG. 3D, an electronic device fabricated according to another example embodiment will be described below.

As illustrated in FIG. 3D, an interlayer insulating layer 105 may be formed on a semiconductor substrate 100 including a first area W1 and a second area W2. The semiconductor substrate 100 may be a semiconductor wafer with an integrated circuit, for example. The first area W1 may be a ball landing portion, and the second area W2 may be a dummy area or a cut area.

The interlayer insulating layer 105 may be a silicon oxide layer, or similar insulating layer. A lower metal pattern 110 may be formed on the interlayer insulating layer 105. The lower metal pattern 110 may be a metal layer electrically connected to the integrated circuit, for example, metal pads, such as ground pads, power pads and/or signal pads.

A lower insulating layer 115 may be formed on the lower metal pattern 110 on the substrate. A metal interconnection 125 extending from the first area W1 to the second area W2 may be formed on the lower insulating layer 115. The metal interconnection 125 may be electrically connected to the lower metal pattern 110 through the lower insulating later 115. The metal interconnection 125 may be a copper layer, an aluminum layer, etc.

An upper insulating layer 130 may be formed on the metal interconnection 125 on the substrate. The upper insulating layer 130 may include a first opening 130a exposing the metal interconnection 125′ positioned on the second area W2, and a second opening 130b exposing the metal interconnection 125 positioned on the first area W1.

A sacrificial pattern 135 may be formed on the metal interconnection 125 exposed by the first opening 130a. The sacrificial pattern 135 may include a Fe element, a Zn element, an Al element, a Ni element, a Sn element, and/or a Pb element, or the like. For example, the sacrificial pattern 135 may be a plated Zn layer. The sacrificial pattern 135 may serve as a sacrificial anode used in cathodic protection. For example, the sacrificial pattern 135 may be a sacrificial anode, and the metal interconnection 125 may be a protected cathode. Accordingly, the sacrificial pattern 135 may corrode and impede or prevent corrosion of the metal interconnection 125 during a process that exposes the metal interconnection 125 by the second opening 130b. Thus, deterioration of electrical characteristic of the electronic device may be reduced or prevented.

A conductive pattern 140 may be formed on the metal interconnection 125 exposed by the second opening 130b. The conductive pattern 140 may be a metal bump, for example, a gold bump, a tin bump, or a solder bump, or the like.

When the second area W2 is a cut area, a process of cutting the second area W2 may be performed. Thus, a plurality of single chip modules may be formed, which may be packaged at the wafer level, for example.

Example embodiments having thus been described, it will be obvious that the same may be varied in many ways. Such variations are not to be regarded as a departure from the intended spirit and scope of example embodiments, and all such modifications as would be obvious to one skilled in the art are intended to be included within the scope of the following claims.

What is claimed is:

1. A method of fabricating an electronic device, comprising:
preparing a substrate with a first area and a second area;
forming a metal interconnection on the substrate extending from the first area to the second area;
forming an insulating layer on the substrate;
forming on the second area a sacrificial pattern electrically connected to the metal interconnection and serving as a sacrificial anode for cathodic protection against corrosion of the metal interconnection; and
forming an opening to expose the metal interconnection on the first area by patterning the insulating layer.

2. The method of claim 1, wherein the substrate is a semiconductor substrate, a rigid printed circuit board substrate, or a flexible printed circuit board substrate.

3. The method of claim 1, wherein the metal interconnection is formed of a copper layer.

4. The method of claim 1, wherein the sacrificial pattern is composed of iron (Fe), zinc (Zn), aluminum (Al), nickel (Ni), tin (Sn), or lead (Pb).

5. The method of claim 1, wherein the sacrificial pattern penetrates the insulating layer on the second area to contact the metal interconnection.

6. The method of claim 1, further comprising:
forming a conductive pattern on the metal interconnection exposed by the opening, the conductive pattern being a gold bump, a tin bump, or a solder bump.

7. The method of claim 1, wherein the first area is a circuit area, and the second area is a dummy area or a cut area.

8. The method of claim 7, further comprising:
cutting the substrate at the second area to remove the sacrificial pattern.

9. A method of fabricating a semiconductor package, comprising:
preparing a semiconductor substrate with a first area and a second area;
forming a lower metal pattern on the first area of the semiconductor substrate;
forming a lower insulating layer with a via hole on the semiconductor substrate to expose the lower metal pattern;
forming on the lower insulating layer a metal interconnection electrically connected to the lower metal pattern by the via hole and extending from the first area to the second area;
forming on the semiconductor substrate an upper insulating layer including a first opening exposing the metal interconnection on the second area;
forming a sacrificial pattern electrically connected to the metal interconnection exposed by the first opening and serving as a sacrificial anode for cathodic protection; and
forming a second opening to expose the metal interconnection on the first area by patterning the upper insulating layer.

10. The method of claim 9, wherein the metal interconnection is formed of a copper layer.

11. The method of claim 9, wherein the sacrificial pattern is composed of iron (Fe), zinc (Zn), aluminum (Al), nickel (Ni), tin (Sn), or lead (Pb).

12. The method of claim 9, further comprising:
forming a conductive pattern on the metal interconnection exposed by the second opening, the conductive pattern being a gold bump, a tin bump, or a solder bump.

13. The method of claim 9, wherein the first area is a circuit area, and the second area is a dummy area or a cut area.

14. An electronic device, comprising:
a substrate with a first area and a second area;
a metal interconnection formed on the substrate and extending from the first area to the second area;
an insulating layer formed on the substrate and including an opening exposing the metal interconnection on the first area; and
a sacrificial pattern penetrating the insulating layer on the second area and electrically connected to the metal interconnection, the sacrificial pattern being configured to serve as a sacrificial anode for cathodic protection against corrosion of the metal interconnection.

15. The device of claim 14, wherein the substrate is a semiconductor substrate, a rigid printed circuit board substrate, or a flexible printed circuit board substrate.

16. The device of claim 14, wherein the metal interconnection includes a copper layer.

17. The device of claim 14, wherein the sacrificial pattern is composed of iron (Fe), zinc (Zn), aluminum (Al), nickel (Ni), tin (Sn), or lead (Pb).

18. The device of claim 14, wherein the sacrificial pattern is a plated metal layer.

19. The device of claim 14, further comprising:
a conductive pattern formed on the metal interconnection exposed by the opening, the conductive pattern being a gold bump, a tin bump, or a solder bump.

20. The device of claim 14, further comprising:
a lower insulating layer formed between the substrate and the metal interconnection; and
a metal pad electrically connected to the metal interconnection and formed between the lower insulating layer and the substrate.

21. The device of claim 14, wherein the first area is a circuit area, and the second area is a dummy area or a cut area.
